(19) United States
(12) Patent Application Publication
(10) Pub. No.: US 2016/0068969 A1
(43) Pub. Date: Mar. 10, 2016

(54) INTEGRATED PROCESSING FOR MICROCONTAMINATION PREVENTION

(71) Applicant: Applied Materials, Inc., Santa Clara, CA (US)

(72) Inventors: Zhenjiang Cui, San Jose, CA (US); Alan Tso, San Jose, CA (US); Anchuan Wang, San Jose, CA (US); Nitin K. Ingle, San Jose, CA (US); Hiroshi Hamana, Hyogo (JP)

(21) Appl. No.: 14/479,030

(22) Filed: Sep. 5, 2014

(51) Int. Cl. C23F 4/00; H01J 37/32

(52) U.S. Cl. CPC C23F 4/00; H01J 37/3244; H01J 37/32733; H01J 2237/334

(57) ABSTRACT

Methods of preventing microcontamination from developing on substrates when the substrates are removed from a substrate processing system are described. During processing in the substrate processing mainframe, fluorine adatoms are present (perhaps left by a prior process in the mainframe) on the surface of the substrate. The fluorine adatoms develop into microcontamination upon exposure to typical atmospheric conditions. A hydrogen-containing precursor is flowed into a remote plasma region to form plasma effluents. The plasma effluents are flowed into a substrate processing region to remove or react with the fluorine adatoms in a treatment operation. Following the treatment operation, the concentration of fluorine on or near the surface is reduced and the development of microcontamination after breaking vacuum is curtailed.

### FIELD

Embodiments of the invention relate to preventing the accumulation of microcontamination.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers or thinning lateral dimensions of features already present on the surface. Often it is desirable to have an etch process which removes one material faster than another helping e.g. a pattern transfer process proceed. Such an etch process is said to be selective to the first material. As a result of the diversity of materials, circuits and processes, etch processes have been developed with a selectivity towards a variety of materials.

Dry etch processes are often desirable for selectively removing material from semiconductor substrates. The desirability stems from the ability to gently remove material from miniature structures with minimal physical disturbance. Dry etch processes also allow the etch rate to be abruptly stopped by removing the gas phase reagents. Some dry-etch processes involve the exposure of a substrate to remote plasma by-products formed from one or more precursors. For example, remote plasma excitation of ammonia and nitrogen trifluoride enables silicon oxide to be selectively removed from a patterned substrate when the plasma effluents are flowed into the substrate processing region.

Methods are needed to broaden the utility of dry-etch processes.

### SUMMARY

Methods of preventing microcontamination from developing on substrates when the substrates are removed from a substrate processing system are described. During processing in the substrate processing mainframe, fluorine adatoms are present (perhaps left by a prior process in the mainframe) on the surface of the substrate. The fluorine adatoms develop into microcontamination upon exposure to typical atmospheric conditions. A hydrogen-containing precursor is flowed into a remote plasma region to form plasma effluents. The plasma effluents are flowed into a substrate processing region to remove or react with the fluorine adatoms in a treatment operation. Following the treatment operation, the concentration of fluorine on or near the surface is reduced and the development of microcontamination after breaking vacuum is curtailed.

Embodiments of the invention include methods of treating a patterned substrate. The methods include placing the patterned substrate into a substrate processing region of a substrate processing chamber. The patterned substrate has an exposed portion having fluorine adatoms bonded to an exposed surface of the exposed portion. The methods further include flowing hydrogen into a remote plasma region while forming a post-treatment plasma in the remote plasma region to produce plasma effluents. The methods further include flowing the plasma effluents into the substrate processing region through through-holes in a showerhead. The methods further include treating the patterned substrate to remove the fluorine adatoms.

Embodiments of the invention include methods of etching a patterned substrate. The methods include placing the patterned substrate in a substrate processing region of a substrate processing chamber. The patterned substrate has a first exposed material. The methods further include flowing a fluorine-containing precursor into a remote plasma region while forming a remote plasma in the remote plasma region to produce plasma effluents. The methods further include flowing the plasma effluents into the substrate processing region through through-holes in a showerhead. The methods further include etching the patterned substrate. The patterned substrate includes a first exposed portion and a second exposed portion. The second exposed portion is etched more slowly than the first exposed material and fluorine residue remains on the patterned substrate after etching the patterned substrate. The methods further include placing the patterned substrate in a post-treatment processing region. The methods further include flowing hydrogen into a second remote plasma region while forming a post-treatment plasma in the second remote plasma region to produce second plasma effluents. The methods further include flowing the second plasma effluents into the post-treatment processing region through through-holes in a showerhead. The methods further include treating the patterned substrate to remove the fluorine residue. The patterned substrate is not exposed to external atmosphere between placing the patterned substrate into the substrate processing region and treating the patterned substrate.

Embodiments of the invention include methods of etching a patterned substrate. The methods include placing the patterned substrate into a substrate processing region of a substrate processing chamber. The patterned substrate includes exposed silicon nitride. The methods further include flowing a nitrogen-and-oxygen-containing precursor and a fluorine-containing precursor into a remote plasma region while forming a remote plasma in the remote plasma region to produce plasma effluents. The methods further include flowing the plasma effluents into the substrate processing region through through-holes in a showerhead. The methods further include etching the exposed silicon nitride. The patterned substrate further includes a second exposed portion. The second exposed portion is etched more slowly than the exposed silicon nitride. The methods further include transferring the patterned substrate from the substrate processing region to a post-treatment processing region without breaking vacuum. The methods further include flowing hydrogen and oxygen into a second remote plasma region while forming a post-treatment plasma in the second remote plasma region to produce second plasma effluents. The methods further include flowing the second plasma effluents into the post-treatment processing region through through-holes in a showerhead. The methods further include treating the patterned substrate to remove fluorine residue.

Additional embodiments and features are set forth in part in the description that follows, and in part will become apparent to those skilled in the art upon examination of the specification or may be learned by the practice of the embodiments. The features and advantages of the embodiments may be realized and attained by means of the instrumentalities, combinations, and methods described in the specification.

### DESCRIPTION OF THE DRAWINGS

A further understanding of the nature and advantages of the embodiments may be realized by reference to the remaining portions of the specification and the drawings.

FIG. 1 is a flow chart of a semiconductor substrate process according to embodiments.

FIG. 2 is a flow chart of a silicon nitride selective etch process according to embodiments.

FIG. 3A shows a schematic cross-sectional view of a substrate processing chamber according to embodiments.

FIG. 3B shows a schematic cross-sectional view of a portion of a substrate processing chamber according to embodiments.

FIG. 3C shows a bottom view of a showerhead according to embodiments.

FIG. 4 shows a top view of an exemplary substrate processing system according to embodiments.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

Methods of preventing microcontamination from developing on substrates when the substrates are removed from a substrate processing system are described. During processing in the substrate processing mainframe, fluorine adatoms are present (perhaps left by a prior process in the mainframe) on the surface of the substrate. The fluorine adatoms develop into microcontamination upon exposure to typical atmospheric conditions. A hydrogen-containing precursor is flowed into a remote plasma region to form plasma effluents. The plasma effluents are flowed into a substrate processing region to remove or react with the fluorine adatoms in a treatment operation. Following the treatment operation, the concentration of fluorine on or near the surface is reduced and the development of microcontamination after breaking vacuum is curtailed.

Fluorine residue may be responsible for the development of microcontamination defects upon exposing a patterned substrate having the fluorine residue to external atmosphere outside a substrate processing mainframe. The moisture in the air may be growing the microcontamination defects over a period of several hours to several days. The growth process may involve the formation of silicic acid in the case of an exposed silicon-containing portion. Taking precautions to avoid developing microcontamination defects improves integrated circuit yield. The treatment processes described herein may reduce or substantially eliminate the growth of microcontamination defects by removing fluorine residue before the patterned substrate is removed from a substrate processing mainframe. The treatment processes may be performed in the same substrate processing mainframe in which a process (for example, an etch process) was performed on the patterned substrate and left the fluorine residue. The fluorine residue may be a in the form of a fluorine adatom bonded either to a surface silicon atom or a surface metal atom.

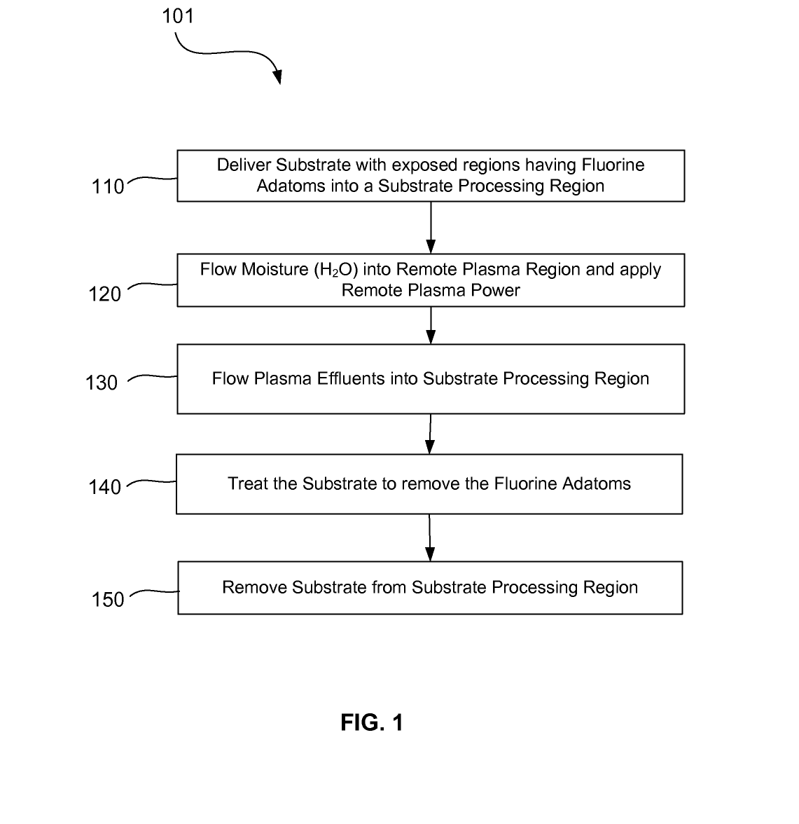

In order to better understand and appreciate the invention, reference is now made to FIG. 1 which is a flow chart of a semiconductor substrate process 101 according to embodiments. Prior to the first operation, a structure is formed in a patterned substrate. The structure possesses exposed portions of two dissimilar materials and possibly more. One of the exposed portions may contain metal atoms or silicon atoms having fluorine adatoms covalently or ionically bonded thereto. A metal atom is an atom which would form conducting material in the absence of any other elements at standard temperature and pressure (STP). The metal atoms or silicon atoms may be bonded to fluorine-adatoms, possibly remaining from a prior etch process. The patterned substrate is then placed in a substrate processing region in operation 110.

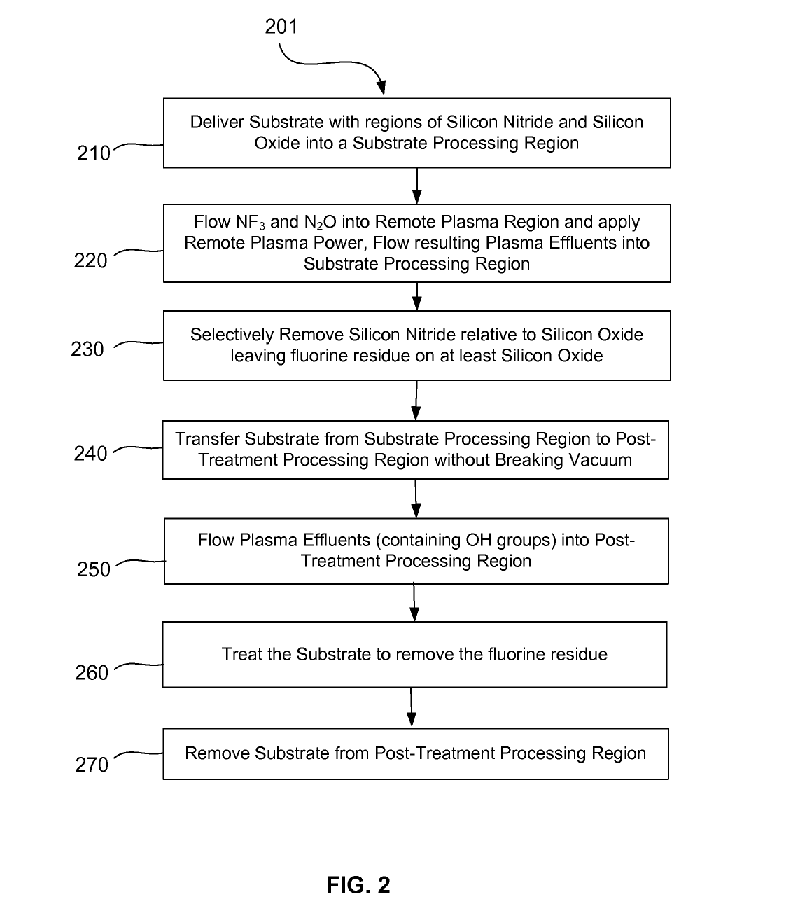

Moisture (H₂O, also referred to herein as water) is flowed into a remote plasma system (operation 120). The H₂O is excited in a remote plasma formed in the remote plasma region. The remote plasma system is positioned next to the substrate processing region and fluidly coupled through a showerhead. More generally, hydrogen is flowed into the remote plasma region in one form or another. For example, a hydrogen-containing precursor may be flowed into the remote plasma system and the hydrogen-containing precursor may comprise at least one precursor selected from H₂O, H₂O₂, H₂ and NH₃. A more complete list of precursor possibilies will be provided when discussing FIG. 2. Removing fluorine adatoms from exposed silicon-containing material (e.g. silicon oxide) has been facilitated by using water or a combination of molecular hydrogen (H₂) and molecular oxygen (O₂). Water or the combination of molecular hydrogen and molecular oxygen are relatively inexpensive ways to create excited OH chemical groups in the plasma effluents. In the case of metal atoms, hydrogen in various forms may be flowed into the remote plasma region to create plasma effluents and the remote plasma region may be devoid of oxygen during the formation of oxygen-free plasma effluents. Flowing hydrogen into the remote plasma region may include flowing a hydrogen-containing precursor including at least one of molecular hydrogen (H₂) and ammonia (NH₃) into the remote plasma region.

In operation 130, the plasma effluents are flowed into the substrate processing region housing the patterned substrate. The patterned substrate is treated with the plasma effluents to remove the fluorine adatoms from the substrate surface in operation 140. The patterned substrate may then be removed from the substrate processing region in operation 150.

Reference is now made to FIG. 2 which is a flow chart of a silicon nitride selective etch process 201 according to embodiments. Prior to the first operation, a structure is formed in a patterned substrate. The structure possesses exposed portions of silicon nitride and silicon oxide (at least). The substrate is delivered into a substrate processing region in operation 210.

Nitrous oxide (N₂O) and nitrogen trifluoride are flowed into a remote plasma region (operation 220) fluidly coupled to the substrate processing region through a showerhead. The nitrous oxide and nitrogen trifluoride are excited in a remote plasma formed in the remote plasma region to produce plasma effluents. More generally, a nitrogen-and-oxygen-containing precursor is flowed into the remote plasma region and the nitrogen-and-oxygen-containing precursor may comprise at least one precursor selected from N₂O, NO, N₂O₂, NO₂. The nitrogen-and-oxygen-containing precursor may consist essentially of or consist of nitrogen and oxygen. Some nitrogen-and-oxygen-containing precursors may be very electronegative and require a high plasma power to form plasma effluents, therefore the nitrogen-and-oxygen-containing precursor may be further excited in a supplementary plasma region in series with the remote plasma region. The supplementary plasma region may be a remote plasma system upstream from the remote plasma region in that effluents generally flow from the supplementary plasma system into the remote plasma region, but not vice versa. Also more generally, a fluorine-containing precursor may be flowed in place of the nitrogen trifluoride. The fluorine-containing precursor may comprise one or more of atomic fluorine, diatomic fluorine, bromine trifluoride, chlorine trifluoride, nitrogen trifluoride, hydrogen fluoride, sulfur hexafluoride, carbon tetrafluoride and xenon difluoride.

The plasma effluents formed in the remote plasma region are flowed into the substrate processing region (operation 220). The patterned substrate is selectively etched (operation 230) such that the exposed silicon nitride is selectively removed at a higher rate than the exposed silicon oxide. Fluorine residue remains on one or both of the silicon nitride or the silicon oxide and may be in the form of fluorine adatoms bonded to surface silicon atoms of either or both exposed portion. The fluorine adatoms increase the risk of developing microcontamination defects upon the removal of the patterned substrate from the substrate processing mainframe as a whole and exposed the patterned substrate to the external atmosphere.

During operation 220, some hydrogen-containing precursors may also be combined with the other precursors or flowed separately into the plasma region, however, the concentration should be kept low. Hydrogen may interact with the fluorine-containing precursor in the plasma to form precursors which remove silicon oxide by forming solid residue by-products on the oxide surface. This reaction reduces the selectivity of the exposed silicon nitride portions as compared with exposed silicon oxide portions. Though some hydrogen may be useful to introduce, there may also be no or essentially no flow of hydrogen into the plasma region during the etch process 100 according to embodiments.

The patterned substrate is removed from the substrate processing region and placed in a post-treatment processing region fluidly coupled to a second remote plasma region in operation 240. An air-tight seal is maintained between the external atmosphere outside the substrate processing mainframe and the interior of substrate processing mainframe during operation 240, a trait which may also be referred to as transferring “without breaking vacuum”. The patterned substrate may be transferred from the substrate processing region to the post-treatment processing region between the etching operation and the treating operation and the patterned substrate may not be exposed to external atmosphere between the etching operation and the treating operation. In other words, the post-treatment processing region may be distinct from the substrate processing region and the second remote plasma region may be distinct from the remote plasma region and vacuum may not be broken while transferring the patterned substrate from the substrate processing region to the post-treatment processing region. In alternative embodiments, the patterned substrate stays in the same substrate processing region for etching and treatment and the second remote plasma region is the same as the remote plasma region used to create the plasma effluents flowed in operation 220.

Moisture is flowed into a remote plasma system and excited in a second remote plasma formed in the second remote plasma region. As before, hydrogen is generally flowed into the second remote plasma system in one form or another. A hydrogen-containing precursor is flowed into the remote plasma region and the hydrogen-containing precursor may comprise at least one precursor selected from H₂O, H₂O₂, H₂ and NH₃. Flowing hydrogen into the remote plasma region may include flowing a hydrogen-containing precursor and an oxygen-containing precursor into the remote plasma region in embodiments. Flowing hydrogen into the remote plasma region may include flowing a hydrogen-and-oxygen-containing precursor into the remote plasma region according to embodiments. Removing fluorine adatoms from exposed silicon-containing material (e.g. silicon oxide) has been facilitated by using water or hydrogen peroxide a combination of molecular hydrogen (H₂) and molecular oxygen (O₂). The hydrogen-containing precursor may be combined with either oxygen or ozone in embodiments. Water or the combination of molecular hydrogen and molecular oxygen are relatively inexpensive ways to create excited OH chemical groups in the plasma effluents. In the case of metal atoms, hydrogen-containing precursors may be flowed into the remote plasma region to create plasma effluents and the remote plasma region may be devoid of oxygen during the formation of the oxygen-free plasma effluents. The hydrogen-containing precursors may include hydrogen (H₂) and/or ammonia (NH₃).

The plasma effluents are flowed into the substrate processing region housing the patterned substrate. OH groups (or O—H groups) are thought to be a component of the plasma effluents and enter the post-treatment processing region as shown in operation 250. The bond between O and H in the OH group is a covalent bond in embodiments. The patterned substrate is treated with the plasma effluents to remove the fluorine adatoms from the substrate surface in operation 260. The reactive chemical species are removed from the substrate processing region and then the patterned substrate may be removed from the substrate processing region in operation 270 according to embodiments.

The method also includes applying power to the fluorine-containing precursor and the nitrogen-and-oxygen-containing precursor (or to the hydrogen-containing precursor during treatments) while they are in the remote plasma regions to generate the plasma effluents. The plasma parameters described herein apply to treatment remote plasmas used to remove fluorine as well as remote plasmas used to etch the patterned substrate. As would be appreciated by one of ordinary skill in the art, the plasma may include a number of charged and neutral species including radicals and ions. The plasma may be generated using known techniques (e.g., RF, capacitively coupled, inductively coupled). In an embodiment, the remote plasma power may be applied to the remote plasma region at a level between 500 W and 5 kW. The remote plasma power may be applied using inductive coils, in embodiments, in which case the remote plasma will be referred to as an inductively-coupled plasma (ICP) or may be applied using capacitive plates, in which case the remote plasma will be referred to as a capacitive-coupled plasma (CCP). According to embodiments, the remote plasma power may be applied to the remote plasma region at a level between 50 W and 500 W. The pressure in all remote plasma regions and all substrate processing regions described herein may be between about 0.01 Torr and 30 Torr or between about 0.1 Torr and 15 Torr in embodiments. The remote plasma region are each disposed remote from the substrate processing region and may be separated from the substrate processing region by an ion suppressor and/or showerhead.

Generally speaking, the patterned substrate will comprise a first exposed portion and a second exposed portion. The first exposed portion, at the very least, will have a materially different stoichiometry from the second exposed portion. The first exposed portion may contain atomic constituents not present in the second exposed portion and vice versa according to embodiments. The first exposed portion may possess no elements present in the second exposed portion in embodiments. For the sake of definition, atomic concentration and presence are defined herein in roughly the first eighty Angstroms of the exposed portions, coinciding with the detection zone for X-ray photoelectron spectroscopy (XPS).

The first exposed portion may be a silicon-containing portion and the second exposed portion may be a metal-containing portion in embodiments. Both the first and second exposed portions may be silicon-containing portions (as is the case with the silicon nitride and silicon oxide example). Both the first and second exposed portions may be metal-containing portions or the first exposed portion may be a metal-containing portion and the second exposed portion may be a silicon-containing portion according to embodiments. As indicated previously, a metal atom is an atom which would form readily conducting material (not a semimetal or semiconductor in embodiments) in the absence of any other elements at standard temperature and pressure (STP).

When there are metal-containing exposed portions on the patterned substrate, hydrogen-containing precursors may be flowed into the remote plasma region to create plasma effluents and the remote plasma region may be devoid of oxygen during the formation of the oxygen-free plasma effluents. The hydrogen-containing precursors may include hydrogen (H₂) and/or ammonia (NH₃). Metal-containing exposed portions may comprise or consist of titanium, titanium nitride, titanium oxide, tantalum, tantalum nitride, tantalum oxide, tungsten, tungsten oxide, cobalt, aluminum, aluminum oxide or aluminum nitride according to embodiments.

For both silicon-containing portions and metal-containing portions, the remote plasma region may be devoid of fluorine during the treatment operations (e.g. operations 140 and 260) according to embodiments. Likewise, the substrate processing region may be devoid of fluorine during treatment in embodiments.

Microcontamination defects were measured by laser detection devices using nominal size thresholds of 35 nm and greater. Surface fluorine concentrations were correlated with presence and essential absence of defects greater than various detection thresholds. Fluorine concentrations were measured using x-ray photoelectron spectroscopy (XPS) which roughly samples the top eighty Angstroms of the exposed surface. The fluorine concentration may vary depending on the material system of the patterned substrate. The fluorine concentration, as measured by x-ray photoelectron spectroscopy, may be reduced from above 6.5% to below 6.5%, may be reduced from above 5.0% to below 5.0% or may be reduced from above 3.5% to below 3.5% during the treating operation according to embodiments. A low microcontamination defect concentration (after exposing the patterned substrate to external atmosphere for several hours) was observed to correlate with XPS atomic fluorine readings of less than 6.5%, 5.0% or 3.5% across various materials used for the exposed portions of the patterned substrate.

For both treatment remote plasmas and etch remote plasmas, the flows of the precursors into the remote plasma region may further include one or more relatively inert gases such as He, N₂, Ar. The inert gas can be used to improve plasma stability, ease plasma initiation, and improve process uniformity. Argon is helpful, as an additive, to promote the formation of a stable plasma. Process uniformity is generally increased when helium is included. These additives are present in embodiments throughout this specification. Flow rates and ratios of the different gases may be used to control etch rates and etch selectivity.

In embodiments, an ion suppressor (which may be the showerhead) may be used to provide radical and/or neutral species for gas-phase etching. The ion suppressor may also be referred to as an ion suppression element. In embodiments, for example, the ion suppressor is used to filter etching plasma effluents en route from the remote plasma region to the substrate processing region. The ion suppressor may be used to provide a reactive gas having a higher concentration of radicals than ions. Plasma effluents pass through the ion suppressor disposed between the remote plasma region and the substrate processing region. The ion suppressor functions to dramatically reduce or substantially eliminate ionic species traveling from the plasma generation region to the substrate. The ion suppressors described herein are simply one way to achieve a low electron temperature in the substrate processing region during the gas-phase etch processes described herein.

In embodiments, an electron beam is passed through the substrate processing region in a plane parallel to the substrate to reduce the electron temperature of the plasma effluents. A simpler showerhead may be used if an electron beam is applied in this manner. The electron beam may be passed as a laminar sheet disposed above the substrate in embodiments. The electron beam provides a source of neutralizing negative charge and provides a more active means for reducing the flow of positively charged ions towards the substrate and increasing the etch selectivity in embodiments. The flow of plasma effluents and various parameters governing the operation of the electron beam may be adjusted to lower the electron temperature measured in the substrate processing region.

The electron temperature may be measured using a Langmuir probe in the substrate processing region during excitation of a plasma in the remote plasma. In aluminum removal embodiments, the electron temperature may be less than 0.5 eV, less than 0.45 eV, less than 0.4 eV, or less than 0.35 eV. These extremely low values for the electron temperature are enabled by the presence of the electron beam, showerhead and/or the ion suppressor. Uncharged neutral and radical species may pass through the electron beam and/or the openings in the ion suppressor to react at the substrate. Such a process using radicals and other neutral species can reduce plasma damage compared to conventional plasma etch processes that include sputtering and bombardment. Embodiments of the present invention are also advantageous over conventional wet etch processes where surface tension of liquids can cause bending and peeling of small features. In point of contrast, the electron temperature during the aluminum oxide removal process may be greater than 0.5 eV, greater than 0.6 eV or greater than 0.7 eV according to embodiments.

The substrate processing region may be described herein as “plasma-free” during the etch processes described herein. “Plasma-free” does not necessarily mean the region is devoid of plasma. Ionized species and free electrons created within the plasma region may travel through pores (apertures) in the partition (showerhead) at exceedingly small concentrations. The borders of the plasma in the chamber plasma region are hard to define and may encroach upon the substrate processing region through the apertures in the showerhead. Furthermore, a low intensity plasma may be created in the substrate processing region without eliminating desirable features of the etch processes described herein. All causes for a plasma having much lower intensity ion density than the chamber plasma region during the creation of the excited plasma effluents do not deviate from the scope of “plasma-free” as used herein.

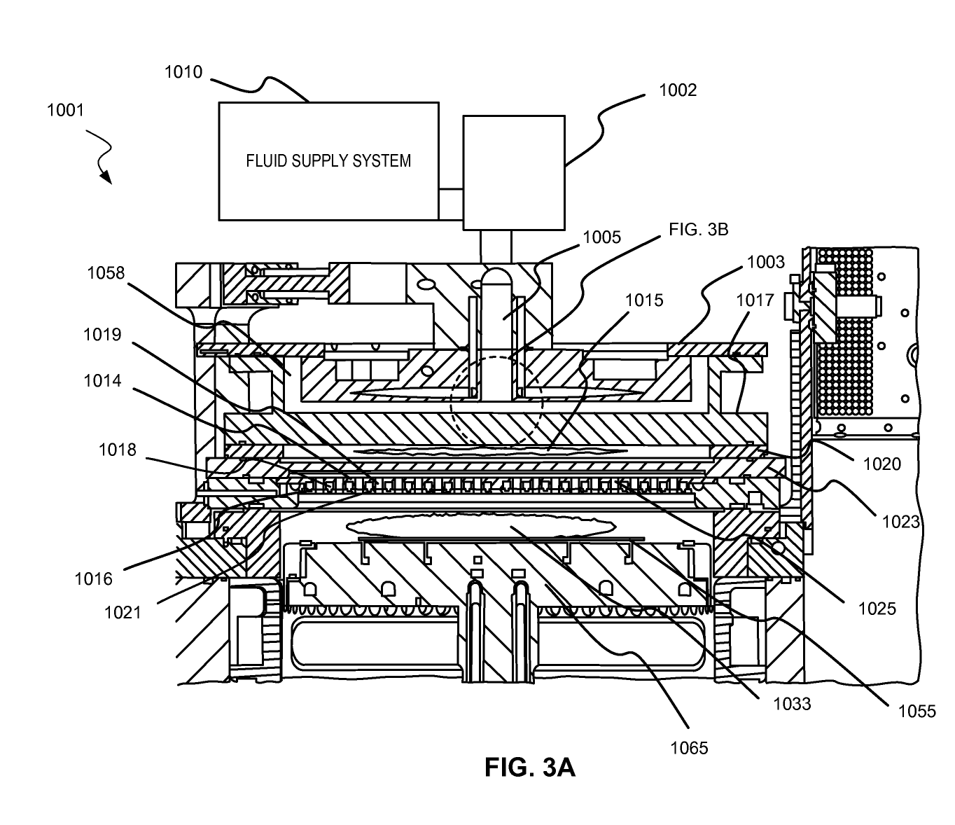

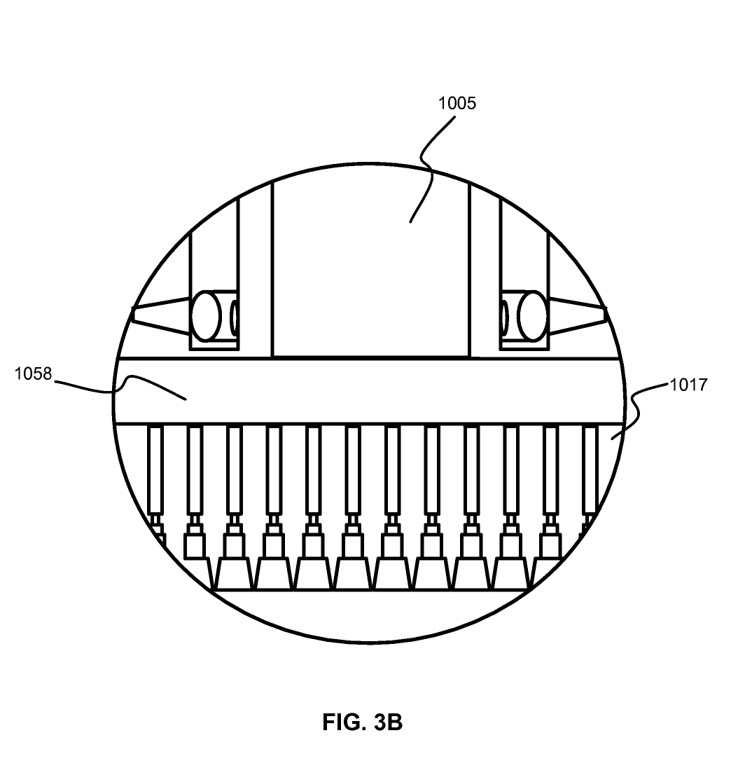

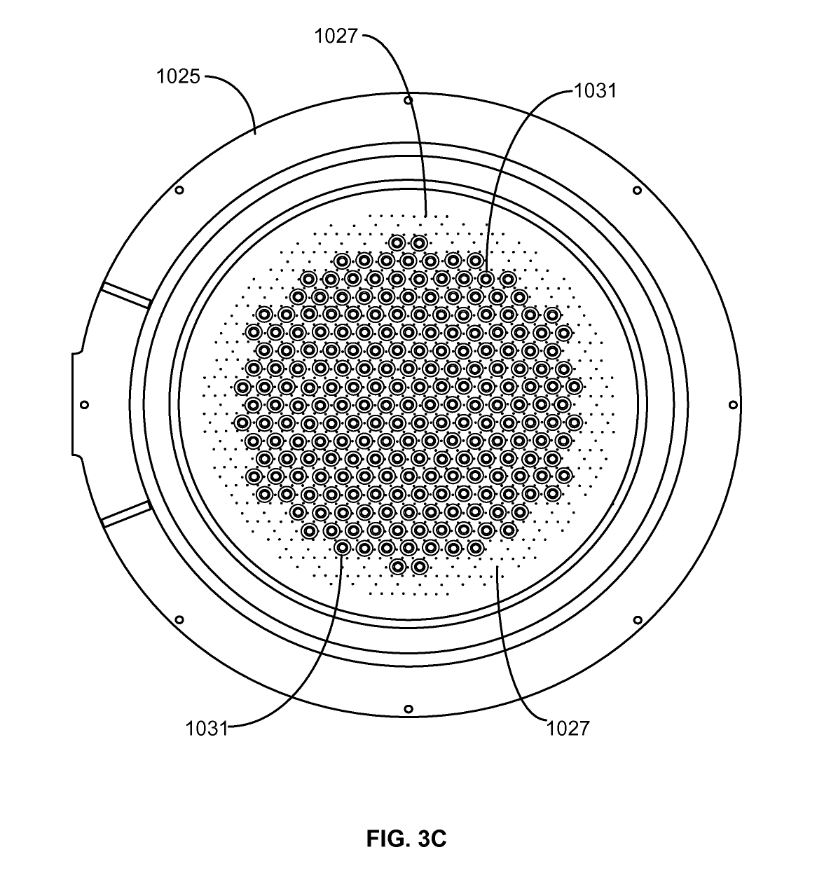

FIG. 3A shows a cross-sectional view of an exemplary substrate processing chamber 1001 with a partitioned plasma generation region within the processing chamber. During film etching, a process gas may be flowed into chamber plasma region 1015 through a gas inlet assembly 1005. A remote plasma system (RPS) 1002 may optionally be included in the system, and may process a first gas which then travels through gas inlet assembly 1005. The process gas may be excited within RPS 1002 prior to entering chamber plasma region 1015. Accordingly, the fluorine-containing precursor as discussed above, for example, may pass through RPS 1002 or bypass the RPS unit in embodiments.

A cooling plate 1003, faceplate 1017, ion suppressor 1023, showerhead 1025, and a substrate support 1065 (also known as a pedestal), having a substrate 1055 disposed thereon, are shown and may each be included according to embodiments. Pedestal 1065 may have a heat exchange channel through which a heat exchange fluid flows to control the temperature of the substrate. This configuration may allow the substrate 1055 temperature to be cooled or heated to maintain relatively low temperatures, such as between −20° C. to 200° C. Pedestal 1065 may also be resistively heated to relatively high temperatures, such as between 100° C. and 1100° C., using an embedded heater element.

Exemplary configurations may include having the gas inlet assembly 1005 open into a gas supply region 1058 partitioned from the chamber plasma region 1015 by faceplate 1017 so that the gases/species flow through the holes in the faceplate 1017 into the chamber plasma region 1015. Structural and operational features may be selected to prevent significant backflow of plasma from the chamber plasma region 1015 back into the supply region 1058, gas inlet assembly 1005, and fluid supply system 1010. The structural features may include the selection of dimensions and cross-sectional geometries of the apertures in faceplate 1017 to deactivate back-streaming plasma. The operational features may include maintaining a pressure difference between the gas supply region 1058 and chamber plasma region 1015 that maintains a unidirectional flow of plasma through the showerhead 1025. The faceplate 1017, or a conductive top portion of the chamber, and showerhead 1025 are shown with an insulating ring 1020 located between the features, which allows an AC potential to be applied to the faceplate 1017 relative to showerhead 1025 and/or ion suppressor 1023. The insulating ring 1020 may be positioned between the faceplate 1017 and the showerhead 1025 and/or ion suppressor 1023 enabling a capacitively coupled plasma (CCP) to be formed in the first plasma region.

The plurality of holes in the ion suppressor 1023 may be configured to control the passage of the activated gas, i.e., the ionic, radical, and/or neutral species, through the ion suppressor 1023. For example, the aspect ratio of the holes, or the hole diameter to length, and/or the geometry of the holes may be controlled so that the flow of ionically-charged species in the activated gas passing through the ion suppressor 1023 is reduced. The holes in the ion suppressor 1023 may include a tapered portion that faces chamber plasma region 1015, and a cylindrical portion that faces the showerhead 1025. The cylindrical portion may be shaped and dimensioned to control the flow of ionic species passing to the showerhead 1025. An adjustable electrical bias may also be applied to the ion suppressor 1023 as an additional means to control the flow of ionic species through the suppressor. The ion suppression element 1023 may function to reduce or eliminate the amount of ionically charged species traveling from the plasma generation region to the substrate. Uncharged neutral and radical species may still pass through the openings in the ion suppressor to react with the substrate.

Plasma power can be of a variety of frequencies or a combination of multiple frequencies. In the exemplary processing system the plasma may be provided by RF power delivered to faceplate 1017 relative to ion suppressor 1023 and/or showerhead 1025. The RF power may be between about 10 watts and about 5000 watts, between about 100 watts and about 2000 watts, between about 200 watts and about 1500 watts, or between about 200 watts and about 1000 watts in embodiments. The RF frequency applied in the exemplary processing system may be low RF frequencies less than about 200 kHz, high RF frequencies between about 10 MHz and about 15 MHz, or microwave frequencies greater than or about 1 GHz in embodiments. The plasma power may be capacitively-coupled (CCP) or inductively-coupled (ICP) into the remote plasma region.

A precursor, for example a fluorine-containing precursor, may be flowed into substrate processing region 1033 by embodiments of the showerhead described herein. Excited species derived from the process gas in chamber plasma region 1015 may travel through apertures in the ion suppressor 1023, and/or showerhead 1025 and react with an additional precursor flowing into substrate processing region 1033 from a separate portion of the showerhead. Alternatively, if all precursor species are being excited in chamber plasma region 1015, no additional precursors may be flowed through the separate portion of the showerhead. Little or no plasma may be present in substrate processing region 1033 during the remote plasma etch process. Excited derivatives of the precursors may combine in the region above the substrate and/or on the substrate to etch structures or remove species from the substrate.

The processing gases may be excited in chamber plasma region 1015 and may be passed through the showerhead 1025 to substrate processing region 1033 in the excited state. While a plasma may be generated in substrate processing region 1033, a plasma may alternatively not be generated in the processing region. In one example, the only excitation of the processing gas or precursors may be from exciting the processing gases in chamber plasma region 1015 to react with one another in substrate processing region 1033. As previously discussed, this may be to protect the structures patterned on substrate 1055.

FIG. 3B shows a detailed view of the features affecting the processing gas distribution through faceplate 1017. The gas distribution assemblies such as showerhead 1025 for use in the processing chamber section 1001 may be referred to as dual channel showerheads (DCSH) and are additionally detailed in the embodiments described in FIG. 3A as well as FIG. 3C herein. The dual channel showerhead may provide for etching processes that allow for separation of etchants outside of the processing region 1033 to provide limited interaction with chamber components and each other prior to being delivered into the processing region.

The showerhead 1025 may comprise an upper plate 1014 and a lower plate 1016. The plates may be coupled with one another to define a volume 1018 between the plates. The coupling of the plates may be so as to provide first fluid channels 1019 through the upper and lower plates, and second fluid channels 1021 through the lower plate 1016. The formed channels may be configured to provide fluid access from the volume 1018 through the lower plate 1016 via second fluid channels 1021 alone, and the first fluid channels 1019 may be fluidly isolated from the volume 1018 between the plates and the second fluid channels 1021. The volume 1018 may be fluidly accessible through a side of the gas distribution assembly 1025. Although the exemplary system of FIGS. 3A-3C includes a dual-channel showerhead, it is understood that alternative distribution assemblies may be utilized that maintain first and second precursors fluidly isolated prior to substrate processing region 1033. For example, a perforated plate and tubes underneath the plate may be utilized, although other configurations may operate with reduced efficiency or not provide as uniform processing as the dual-channel showerhead as described.

In the embodiment shown, showerhead 1025 may distribute via first fluid channels 1019 process gases which contain plasma effluents upon excitation by a plasma in chamber plasma region 1015. In embodiments, the process gas introduced into RPS 1002 and/or chamber plasma region 1015 may contain fluorine, e.g., NF₃. The process gas may also include a carrier gas such as helium, argon, nitrogen (N₂), etc. Plasma effluents may include ionized or neutral derivatives of the process gas and may also be referred to herein as a radical-fluorine precursor referring to the atomic constituent of the process gas introduced.

FIG. 3C is a bottom view of a showerhead 1025 for use with a processing chamber in embodiments. Showerhead 1025 corresponds with the showerhead shown in FIG. 3A. Through-holes 1031, which show a view of first fluid channels 1019, may have a plurality of shapes and configurations to control and affect the flow of precursors through the showerhead 1025. Small holes 1027, which show a view of second fluid channels 1021, may be distributed substantially evenly over the surface of the showerhead, even amongst the through-holes 1031, which may help to provide more even mixing of the precursors as they exit the showerhead than other configurations.

The chamber plasma region 1015 or a region in an RPS may be referred to as a remote plasma region. In embodiments, the radical fluorine precursor is created in the remote plasma region and travels into the substrate processing region where it may or may not combine with additional precursors. In embodiments, the additional precursors are excited only by the radical-fluorine precursor. Plasma power may essentially be applied only to the remote plasma region in embodiments to ensure that the radical-fluorine precursor provides the dominant excitation. NF₃ or another fluorine-containing precursor may be flowed into chamber plasma region 1015 at rates between about 5 sccm and about 500 sccm, between about 10 sccm and about 150 sccm, or between about 25 sccm and about 125 sccm in embodiments.

Combined flow rates of precursors into the chamber may account for 0.05% to about 20% by volume of the overall gas mixture; the remainder being carrier gases. The fluorine-containing precursor may be flowed into the remote plasma region, but the plasma effluents may have the same volumetric flow ratio in embodiments. In the case of the fluorine-containing precursor, a purge or carrier gas may be first initiated into the remote plasma region before the fluorine-containing gas to stabilize the pressure within the remote plasma region. Substrate processing region 1033 can be maintained at a variety of pressures during the flow of precursors, any carrier gases, and plasma effluents into substrate processing region 1033. The pressure may be maintained between 0.1 mTorr and 100 Torr, between 1 Torr and 20 Torr or between 1 Torr and 5 Torr in embodiments.

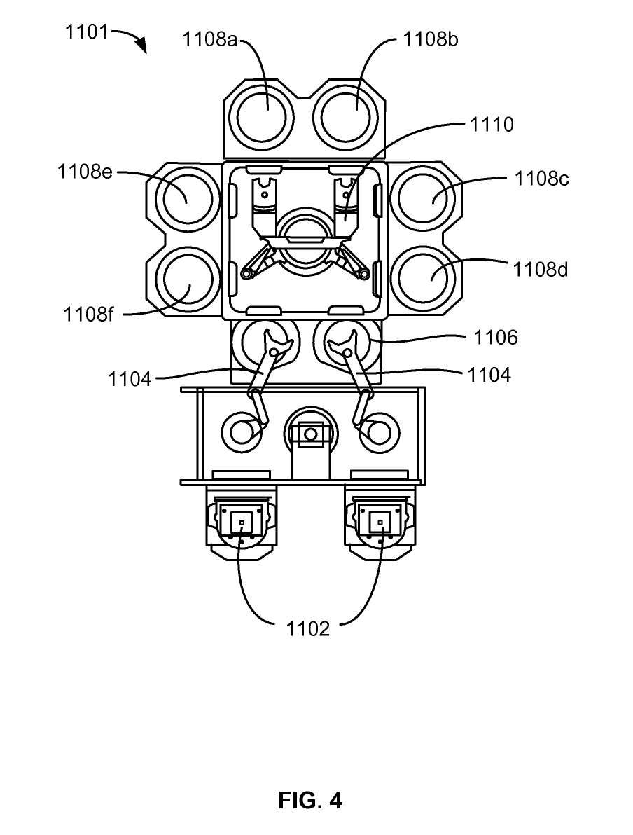

Embodiments of the dry etch systems may be incorporated into larger fabrication systems for producing integrated circuit chips. FIG. 4 shows one such processing system (mainframe) 1101 of deposition, etching, baking, and curing chambers in embodiments. In the figure, a pair of front opening unified pods (load lock chambers 1102) supply substrates of a variety of sizes that are received by robotic arms 1104 and placed into a low pressure holding area 1106 before being placed into one of the substrate processing chambers 1108a-f. A second robotic arm 1110 may be used to transport the substrate wafers from the holding area 1106 to the substrate processing chambers 1108a-f and back. Each substrate processing chamber 1108a-f, can be outfitted to perform a number of substrate processing operations including the dry etch processes described herein in addition to cyclical layer deposition (CLD), atomic layer deposition (ALD), chemical vapor deposition (CVD), physical vapor deposition (PVD), etch, pre-clean, degas, orientation, and other substrate processes.

Low pressure holding area 1106 is typically used as a transfer area between robotic arms 1104 and second robotic arm 1110. There may be two substrate transfer levels in low pressure holding area 1106. The lower level may be used to transfer substrates towards the substrate processing chambers 1108 and the upper level may be used to transfer substrates toward the pair of front opening unified pods 1102. In one configuration, the upper level may be equipped with a remote plasma region for creating plasma effluents from a hydrogen-containing precursor, and treating a patterned substrate to remove fluorine residue. The substrate processing chambers 1108a-f may be configured for depositing, annealing, curing and/or etching a film on the substrate wafer. In one configuration, all three pairs of chambers, e.g., 1108a-f, may be configured to etch a film on the substrate.

In the preceding description, for the purposes of explanation, numerous details have been set forth to provide an understanding of various embodiments of the present invention. It will be apparent to one skilled in the art, however, that certain embodiments may be practiced without some of these details, or with additional details.

As used herein “substrate” may be a support substrate with or without layers formed thereon. The patterned substrate may be an insulator or a semiconductor of a variety of doping concentrations and profiles and may, for example, be a semiconductor substrate of the type used in the manufacture of integrated circuits. Exposed “silicon” or “polysilicon” of the patterned substrate is predominantly Si but may include minority concentrations of other elemental constituents such as nitrogen, oxygen, hydrogen and carbon. Exposed “silicon” or “polysilicon” may consist of or consist essentially of silicon. Exposed “silicon nitride” of the patterned substrate is predominantly silicon and nitrogen but may include minority concentrations of other elemental constituents such as oxygen, hydrogen and carbon. “Exposed silicon nitride” may consist essentially of or consist of silicon and nitrogen. Exposed “silicon oxide” of the patterned substrate is predominantly SiO₂ but may include minority concentrations of other elemental constituents such as nitrogen, hydrogen and carbon. In embodiments, silicon oxide films etched using the methods taught herein consist essentially of or consist of silicon and oxygen. Analogous definitions will be understood for “titanium”, “titanium nitride”, “tantalum”, “tantalum nitride” and the other metal-containing exposed portions recited herein.

The term “precursor” is used to refer to any process gas which takes part in a reaction to either remove material from or deposit material onto a surface. “Plasma effluents” describe gas exiting from the chamber plasma region and entering the substrate processing region. Plasma effluents are in an “excited state” wherein at least some of the gas molecules are in vibrationally-excited, dissociated and/or ionized states. A “radical precursor” is used to describe plasma effluents (a gas in an excited state which is exiting a plasma) which participate in a reaction to either remove material from or deposit material on a surface. “Radical-fluorine” are radical precursors which contain fluorine but may contain other elemental constituents. The phrase “inert gas” refers to any gas which does not form chemical bonds when etching or being incorporated into a film. Exemplary inert gases include noble gases but may include other gases so long as no chemical bonds are formed when (typically) trace amounts are trapped in a film.

The terms “gap” and “trench” are used throughout with no implication that the etched geometry has a large horizontal aspect ratio. Viewed from above the surface, trenches may appear circular, oval, polygonal, rectangular, or a variety of other shapes. A trench may be in the shape of a moat around an island of material. The term “via” is used to refer to a low aspect ratio trench (as viewed from above) which may or may not be filled with metal to form a vertical electrical connection. As used herein, an isotropic or a conformal etch process refers to a generally uniform removal of material on a surface in the same shape as the surface, i.e., the surface of the etched layer and the pre-etch surface are generally parallel. A person having ordinary skill in the art will recognize that the etched interface likely cannot be 100% conformal and thus the term “generally” allows for acceptable tolerances.

Having disclosed several embodiments, it will be recognized by those of skill in the art that various modifications, alternative constructions, and equivalents may be used without departing from the spirit of the disclosed embodiments. Additionally, a number of well-known processes and elements have not been described to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the dielectric material” includes reference to one or more dielectric materials and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

1. A method of treating a patterned substrate, the method comprising:
placing the patterned substrate into a substrate processing region of a substrate processing chamber, wherein the patterned substrate comprises an exposed portion having fluorine adatoms bonded to an exposed surface of the exposed portion;
flowing hydrogen into a remote plasma region while forming a post-treatment plasma in the remote plasma region to produce plasma effluents;
flowing the plasma effluents into the substrate processing region through through-holes in a showerhead; and
treating the patterned substrate to remove the fluorine adatoms.

2. The method of claim 1 wherein flowing hydrogen into the remote plasma region comprises flowing a hydrogen-containing precursor and an oxygen-containing precursor into the remote plasma region.

3. The method of claim 1 wherein flowing hydrogen into the remote plasma region comprises flowing a hydrogen-and-oxygen-containing precursor into the remote plasma region.

4. The method of claim 3 wherein the hydrogen-and-oxygen-containing precursor comprises moisture.

5. The method of claim 1 wherein flowing hydrogen into the remote plasma region comprises flowing one of molecular hydrogen (H₂) or ammonia (NH₃) into the remote plasma region.

6. The method of claim 1 wherein the fluorine adatoms are bonded to metal atoms present in the exposed surface.

7. The method of claim 1 wherein the fluorine adatoms are bonded to silicon atoms present in the exposed surface.

8. A method of etching a patterned substrate, the method comprising:
placing the patterned substrate in a substrate processing region of a substrate processing chamber, wherein the patterned substrate comprises a first exposed material;
flowing a fluorine-containing precursor into a remote plasma region while forming a remote plasma in the remote plasma region to produce plasma effluents;
flowing the plasma effluents into the substrate processing region through through-holes in a showerhead;
etching the patterned substrate, wherein the patterned substrate comprises a first exposed portion and a second exposed portion, wherein the second exposed portion is etched more slowly than the first exposed material and wherein fluorine residue remains on the patterned substrate after etching the patterned substrate;
placing the patterned substrate in a post-treatment processing region;
flowing hydrogen into a second remote plasma region while forming a post-treatment plasma in the second remote plasma region to produce second plasma effluents;
flowing the second plasma effluents into the post-treatment processing region through through-holes in a showerhead; and
treating the patterned substrate to remove the fluorine residue, wherein the patterned substrate is not exposed to external atmosphere between placing the patterned substrate into the substrate processing region and treating the patterned substrate.

9. The method of claim 8 wherein the fluorine-containing precursor comprises a precursor selected from the group consisting of hydrogen fluoride, atomic fluorine, diatomic fluorine, nitrogen trifluoride, carbon tetrafluoride and xenon difluoride.

10. The method of claim 8 wherein the second plasma effluents comprise OH groups.

11. The method of claim 8 wherein the second remote plasma region is the same as the remote plasma region and the post-treatment processing region is the same as the substrate processing region.

12. The method of claim 8 wherein the post-treatment processing region is distinct from the substrate processing region and the second remote plasma region is distinct from the remote plasma region and vacuum is not broken while transferring the patterned substrate from the substrate processing region to the post-treatment processing region.

13. The method of claim 12 further comprising transferring the patterned substrate from the substrate processing region to the post-treatment processing region between the etching operation and the treating operation, wherein the patterned substrate is not exposed to external atmosphere between the etching operation and the treating operation.

14. A method of etching a patterned substrate, the method comprising:
placing the patterned substrate into a substrate processing region of a substrate processing chamber, wherein the patterned substrate comprises exposed silicon nitride;
flowing a nitrogen-and-oxygen-containing precursor and a fluorine-containing precursor into a remote plasma region while forming a remote plasma in the remote plasma region to produce plasma effluents;
flowing the plasma effluents into the substrate processing region through through-holes in a showerhead;
etching the exposed silicon nitride, wherein the patterned substrate further comprises a second exposed portion, wherein the second exposed portion is etched more slowly than the exposed silicon nitride;
transferring the patterned substrate from the substrate processing region to a post-treatment processing region without breaking vacuum;
flowing hydrogen and oxygen into a second remote plasma region while forming a post-treatment plasma in the second remote plasma region to produce second plasma effluents;
flowing the second plasma effluents into the post-treatment processing region through through-holes in a showerhead; and
treating the patterned substrate to remove fluorine residue.

15. The method of claim 14 wherein a fluorine concentration, as measured by x-ray photoelectron spectroscopy, is reduced from above 6.5% to below 6.5% during the treating operation.

16. The method of claim 14 wherein flowing the hydrogen and oxygen comprises flowing moisture (H₂O) into the second remote plasma region.
